(19) United States
(12) Patent Application Publication
(10) Pub. No.: US 2013/0248912 A1
(43) Pub. Date: Sep. 26, 2013

(54) SEMICONDUCTOR LIGHT EMITTING ELEMENT

(71) Applicant: KABUSHIKI KAISHA TOSHIBA, Tokyo (JP)

(72) Inventors: Kenji NAKAMURA, Kanagawa-ken (JP); Akira Fujimoto, Kanagawa-ken (JP); Tsutomu Nakanishi, Tokyo (JP); Ryota Kitagawa, Tokyo (JP); Koji Asakawa, Kanagawa-ken (JP); Takanobu Kamakura, Fukuoka-ken (JP); Shinji Nunotani, Fukuoka-ken (JP)

(73) Assignee: KABUSHIKI KAISHA TOSHIBA, Tokyo (JP)

(21) Appl. No.: 13/849,822

(22) Filed: Mar. 25, 2013

(30) Foreign Application Priority Data
Mar. 26, 2012 (JP) 2012-070227

(51) Int. Cl. H01L 33/58

(52) U.S. Cl. CPC H01L 33/58
USPC 257/98

(57) ABSTRACT

According to one embodiment, a semiconductor light emitting element includes a stacked body and an optical layer. The stacked body has a major surface and includes a light emitting layer. The optical layer is in contact with the surface and includes a dielectric body, first particles, and second particles. The optical layer includes a first region including the dielectric body and the first particles and does not include the second particles and a second region including the dielectric body and the second particles. A sphere-equivalent diameter of the first particle is not less than 1 nanometer and not more than 100 nanometers. A sphere-equivalent diameter of the second particle is more than 300 nanometers and less than 1000 nanometers. An average refractive index of the first region is larger than a refractive index of the stacked body and smaller than a refractive index of the second particle.

### CROSS-REFERENCE TO RELATED APPLICATIONS

This application is based upon and claims the benefit of priority from the prior Japanese Patent Application No. 2012-070227, filed on Mar. 26, 2012; the entire contents of which are incorporated herein by reference.

### FIELD

Embodiments described herein relate generally to a semiconductor light emitting element.

### BACKGROUND

It is required for semiconductor light emitting elements to have high brightness properties in order to improve visibility and efficiency. In the semiconductor light emitting element, high brightness properties are achieved by forming a concavoconvex structure on a main light extraction surface. In such a concavoconvex structure, an optical phenomenon depending on the concavoconvex period with respect to the wavelength of light may occur.

When light is applied to a light extraction surface having a concavoconvex structure with a period much larger than the wavelength of the light, the light acts pursuant to geometrical-optical behavior. In the case where a concavo-convex structure with a period of approximately one to several times the wavelength of light is formed on the light extraction surface, the light is diffracted. In the case where a concavo-convex structure with a period sufficiently smaller than the wavelength of light is formed on the light extraction surface, a GI (graded index) structure is produced in which the average refractive index continuously changes from the interior of a substrate toward the outside in a range of approximately the wavelength of the light. Consequently, Fresnel reflection within the critical angle is reduced.

In such a semiconductor light emitting element, it is desired to further improve the light extraction efficiency.

### BRIEF DESCRIPTION OF THE DRAWINGS

FIG. 1 is a schematic view illustrating a configuration of a semiconductor light emitting element according to a first embodiment;

FIGS. 2A and 2B are diagrams illustrating a transmittance of light in a case of having a concavoconvex structure;

FIGS. 3A and 3B are diagrams illustrating a transmittance of light of the semiconductor light emitting element according to the embodiment;

FIGS. 4A and 4B are schematic diagrams showing effects of an optical layer;

FIGS. 5A and 5B are schematic diagrams illustrating parameters of Mathematical Formula;

FIG. 6 is a schematic diagram illustrating a configuration of a measurement apparatus of a light extraction efficiency;

FIG. 7 is a diagram showing a relationship between a first region and a refractive index;

FIG. 8 is a diagram illustrating simulation results showing a relationship between a wavelength and a light transmittance;

FIG. 9 to FIG. 11 are diagrams illustrating simulation results of a direction of scattering due to a second particle; and

FIG. 12 to FIG. 14 are diagrams showing simulation calculation results of light transmittance versus incident angle.

### DETAILED DESCRIPTION

In general, according to one embodiment, a semiconductor light emitting element includes a stacked body having a major surface and including a light emitting layer and an optical layer provided in contact with the major surface of the stacked body and including a dielectric body, a plurality of first particles having a refractive index different from a refractive index of the dielectric body, and a plurality of second particles having a refractive index different from a refractive index of the dielectric body, the optical layer including a first region including the dielectric body and the plurality of first particles and not including the plurality of second particles; and a second region including the dielectric body and the plurality of second particles, a sphere-equivalent diameter of the first particle being not less than 1 nanometer and not more than 100 nanometers, a sphere-equivalent diameter of the second particle being more than 300 nanometers and less than 1000 nanometers, an average refractive index of the first region being larger than a refractive index of the stacked body and smaller than a refractive index of the second particle.

Hereinbelow, embodiments of the invention are described based on the drawings.

The drawings are schematic or conceptual; and the relationships between the thickness and width of portions, the proportions of sizes among portions, etc. are not necessarily the same as the actual values thereof. Further, the dimensions and proportions may be illustrated differently among drawings, even for identical portions.

In the specification of this application and the drawings, components similar to those described in regard to a drawing thereinabove are marked with the same reference numerals, and a detailed description is omitted as appropriate.

In the following description, as an example, specific examples are given in which the first conductivity type is the n-type and the second conductivity type is the p-type.

### First Embodiment

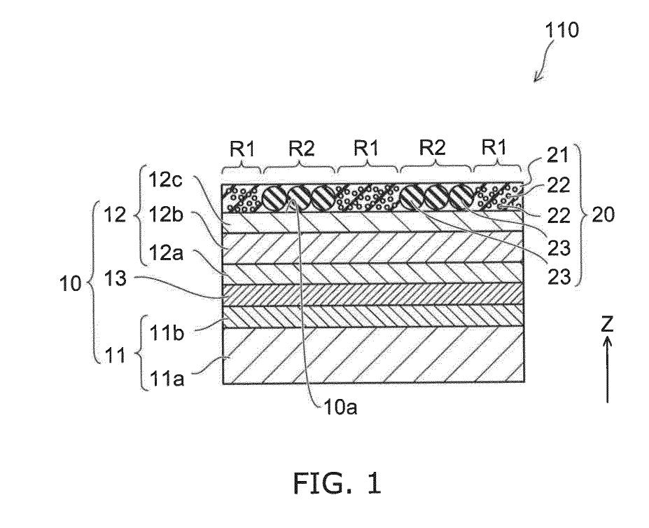

FIG. 1 is a schematic view illustrating the configuration of a semiconductor light emitting element according to a first embodiment.

As shown in FIG. 1, a semiconductor light emitting element 110 according to the first embodiment includes a stacked body 10 and an optical layer 20.

The stacked body 10 includes a first semiconductor layer 11 of a first conductivity type, a second semiconductor layer 12 of a second conductivity type, and a light emitting layer 13 provided between the first semiconductor layer 11 and the second semiconductor layer 12. The stacked body 10 has a major surface 10a on the side of the second semiconductor layer 12. In the embodiment, the direction perpendicular to the major surface 10a is referred to as a Z direction.

The first semiconductor layer 11 includes, for example, a cladding layer 11b. The cladding layer 11b is formed on a substrate 11a. In the embodiment, for the sake of convenience, it is assumed that the substrate 11a is included in the first semiconductor layer 11.

The second semiconductor layer 12 includes, for example, a cladding layer 12a. A current spreading layer 12b, for example, is provided on the cladding layer 12a, and a contact layer 12c is provided thereon. In the embodiment, for the sake of convenience, it is assumed that the current spreading layer 12b and the contact layer 12c are included in the second semiconductor layer 12.

The light emitting layer 13 is provided between the first semiconductor layer 11 and the second semiconductor layer 12. In the semiconductor light emitting element 110, for example, a hetero-structure is formed by the cladding layer 12b of the first semiconductor layer 11, the light emitting layer 13, and the cladding layer 12a of the second semiconductor layer 12.

The light emitting layer 13 may be, for example, an MQW (multiple quantum well) configuration in which barrier layers and well layers are alternately provided in a repeated manner. The light emitting layer 13 may be what includes an SQW (single quantum well) configuration in which one set of a well layer and barrier layers sandwiching the well layer is provided.

A not-shown electrode is provided to each of the first semiconductor layer 11 and the second semiconductor layer 12. By applying a prescribed voltage between the first semiconductor layer 11 and the second semiconductor layer 12, light having a prescribed center wavelength (e.g. a wavelength of visible light) is emitted from the light emitting layer 13. The light is mainly emitted from the major surface 10a to the outside. That is, the major surface 10a is one of the main light extraction surfaces of the semiconductor light emitting element 110.

The optical layer 20 is provided in contact with the major surface 10a of the stacked body 10.

The optical layer 20 includes a dielectric body 21, a plurality of first particles 22, and a plurality of second particles 23. The refractive index of the plurality of first particles 22 is different from the refractive index of the dielectric body 21. The refractive index of the plurality of second particles 23 is different from the refractive index of the dielectric body 21. In the embodiment, the refractive index is the refractive index for the wavelength of the light emitted from the light emitting layer 13 unless otherwise specified.

The optical layer 20 includes a first region R1 and a second region R2.

The first region R1 is a region that includes the dielectric body 21 and a plurality of first particles 22 and does not include a plurality of second particles 23. The second region R2 is a region that includes the dielectric body 21 and a plurality of second particles 23.

At least one selected from silicon oxide, an epoxy resin, and a silicone resin is used for the dielectric body 21. The first particle 22 and the second particle 23 are dielectric materials, and an oxide or a nitride of at least one selected from the group consisting of titanium, zinc, tin, indium, zirconium, silicon, and tungsten or polystyrene is used therefor.

In the semiconductor light emitting element 110 according to the embodiment, the sphere-equivalent diameter of the first particle 22 is not less than 1 nanometer and not more than 100 nanometers. The sphere-equivalent diameter of the second particle 23 is more than 300 nanometers and less than 1000 nanometers.

In the embodiment, the sphere-equivalent diameter refers to the volume average diameter of spheres having an equal effect of interaction with light.

The sphere-equivalent diameter is directly measured with, for example, a laser particle size distribution meter.

In the semiconductor light emitting element 110 according to the embodiment, the average refractive index of the first region R1 is larger than the refractive index of the stacked body 10 and smaller than the refractive index of the second particle 23.

In the embodiment, the average refractive index refers to the average value of the refractive index of the dielectric body 21 and the refractive index of the first particle 22 on a volume ratio basis.

By the semiconductor light emitting element 110 thus configured, the extraction efficiency of light emitted from the major surface 10a that is one of the light extraction surfaces (light extraction efficiency) is improved.

In the embodiment, the light extraction efficiency refers to the proportion of the intensity of light that can be extracted to the outside of the semiconductor light emitting element 110 to the intensity of the light generated in the light emitting layer.

Next, the transmittance of light is described.

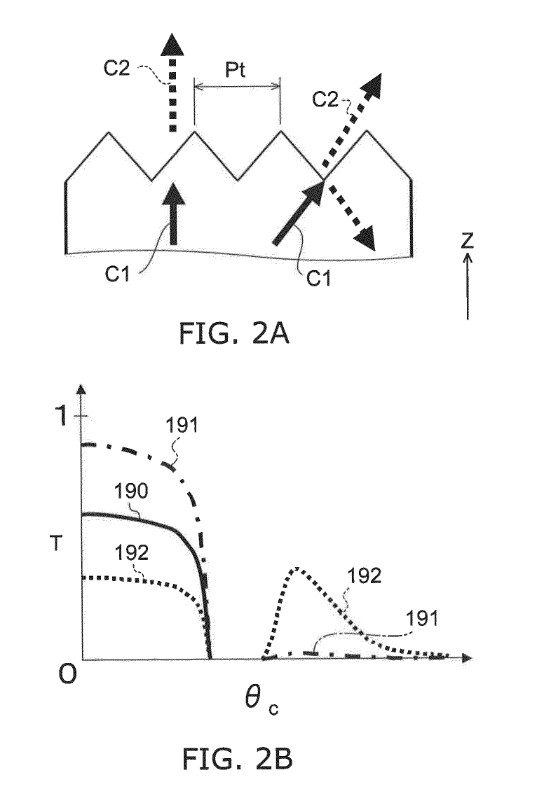

FIGS. 2A and 2B are diagrams illustrating the transmittance of light in the case of having a concavo-convex structure.

FIG. 2A is a schematic cross-sectional view illustrating a concavo-convex structure, and FIG. 2B is a diagram illustrating the transmittance T versus the incident angle θc.

As shown in FIG. 2A, in the case where a concave-convex 15 is provided at the major surface 10a of the stacked body 10, the transmittance T of light emitted from the interior of the stacked body 10 to the outside via the concave-convex 15 changes with the pitch Pt of the concave-convex 15.

When the light traveling from the interior of the stacked body 10 toward the major surface 10a is denoted by C1 and the light emitted from the major surface 10a (the concave-convex 15) to the outside is denoted by C2, the light transmittance T is expressed by the intensity of C2/the intensity of C1. The incident angle of the light C1 with respect to the axis perpendicular to the major surface 10a is referred to as an incident angle θc.

FIG. 2B shows examples of the light transmittance T versus the incident angle θc of semiconductor light emitting elements 190, 191, and 192. Here, the semiconductor light emitting element 190 has a structure in which the concave-convex 15 is not provided at the major surface 10a, the semiconductor light emitting element 191 has a structure in which the concave-convex 15 with a relatively small pitch Pt is provided at the major surface 10a, and the semiconductor light emitting element 192 has a structure in which the concave-convex 15 with a relatively large pitch Pt is provided at the major surface 10a.

The stacked body 10 of the semiconductor light emitting element generally has a high refractive index. Therefore, in the semiconductor light emitting element 190 having a flat light extraction surface, light of not less than the critical angle depending on the refractive index of the stacked body 10 included in the semiconductor light emitting element 190 is totally reflected at the light extraction surface (the major surface 10a). Consequently, only part of the light generated in the light emitting layer is emitted to the outside of the semiconductor light emitting element 190.

In the semiconductor light emitting element 191 including the concave-convex 15 with a pitch Pt much smaller than the wavelength of light, a GI structure is produced in which the average refractive index in a range of approximately the wavelength of the light C1 continuously changes from the interior of the stacked body 10 toward the outside. Therefore, Fresnel reflection within the critical angle is reduced as compared to the semiconductor light emitting element 190, and the light transmittance T within the critical angle is improved.

In the semiconductor light emitting element 192 including the concave-convex 15 with a pitch Pt much larger than the wavelength of light, the light C1 acts pursuant to geometrical-optical behavior. In the semiconductor light emitting element 192 including such a concave-convex 15, even when light C1 of not less than the critical angle with respect to the light extraction surface (the major surface 10a) is caused to be incident, the light C1 is transmitted without being totally reflected as long as the light C1 has an incident angle of not more than the critical angle with respect to the surface of the concave-convex 15 provided. Thus, light T in the range exceeding the critical angle is increased as compared to the semiconductor light emitting elements 190 and 191.

Here, in the semiconductor light emitting elements 191 and 192 in which a periodic concavo-convex structure is formed at the light extraction surface (the major surface 10a), since an optical phenomenon corresponding to the pitch Pt of the concave-convex 15 is utilized, the proportion between the light transmittance T within the critical angle and the light transmittance T of not less than the critical angle depends on the pitch Pt of the concave-convex 15. Therefore, it is not possible to obtain a light extraction efficiency of a certain proportion or more to the light extraction efficiency in the semiconductor light emitting element 190 having a flat light extraction surface.

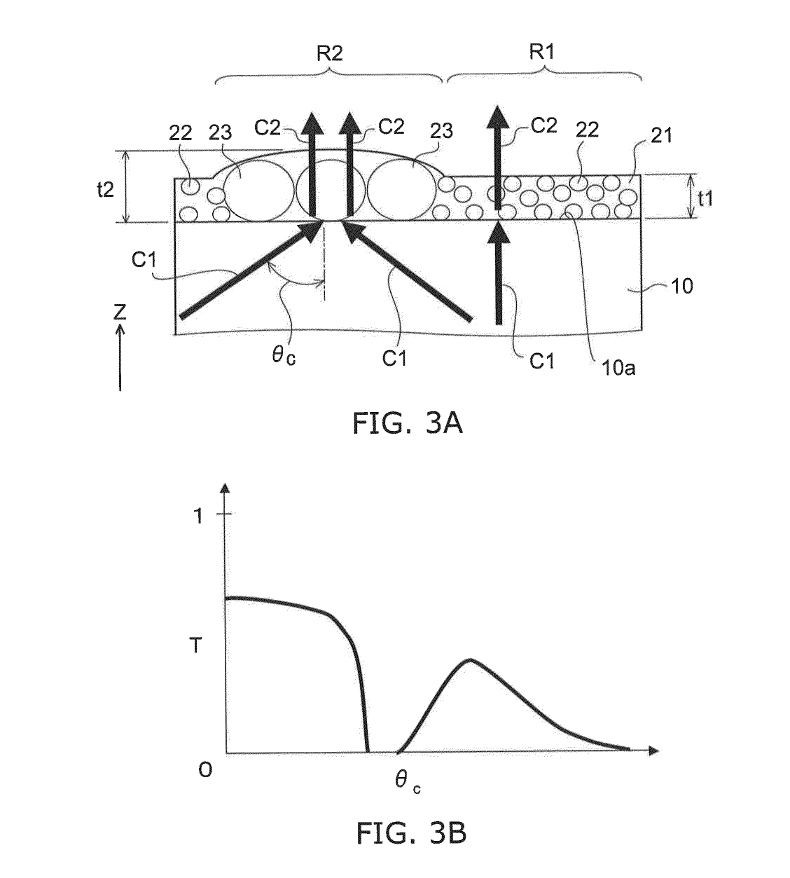

FIGS. 3A and 3B are diagrams illustrating the transmittance of light of the semiconductor light emitting element according to the embodiment.

FIG. 3A is a schematic enlarged cross-sectional view of a portion in and around the optical layer, and FIG. 3B is a diagram illustrating the transmittance T versus the incident angle θc.

As shown in FIG. 3A, the optical layer 20 of the semiconductor light emitting element 110 according to the embodiment includes the first region R1 and the second region R2. The first region R1 is a region in which a plurality of first particles 22 are contained in the dielectric body 21 and the second particle 23 is not contained. The second region R2 is a region in which a plurality of second particles 23 are contained in the dielectric body 21. First particles 22 may be contained in the second region R2.

The distribution (the frequency to the particle size) of the particle size (the sphere-equivalent diameter) of the particles included in the optical layer 20 has a plurality of peaks. The first particle 22 and the second particle 23 are included in a distribution with center at two peaks on the higher frequency side out of the plurality of peaks.

In the particle size distribution of the particles included in the optical layer 20, the peak of the sphere-equivalent diameter of the first particle 22 is in a range of not less than 1 nm and not more than 100 nm, and the peak of the sphere-equivalent diameter of the second particle 23 is in a range of more than 300 nm and less than 1000 nm.

The first region R1 including the first particle 22 provides a reflection prevention effect in the case where the incident angle θc is small (e.g. not more than the critical angle), and the second region R2 including the second particle 23 provides diffraction and scattering effects in the case where the incident angle θc is large (e.g. not less than the critical angle).

Here, if the particle size of the first particle 22 is too small, unintentional mixing-in occurs because of the excessively small particle size, and the characteristics of the objective cannot be obtained. Conversely, if the particle size of the first particle 22 is too large, the effect of the second particle 23 appears because of the proximity to the particle size of the second particle 23, and it is difficult to obtain the effect of particle separation.

If the particle size of the second particle 23 is too small, the effect of the first particle 22 appears because of the proximity to the particle size of the first particle 22, and it is difficult to obtain the effect of particle separation. Conversely, if the particle size of the second particle 23 is too large, it is difficult to obtain a scattering effect.

The sphere-equivalent diameter of the first particle 22 is preferably not less than 1 nm and not more than 70 nm. The sphere-equivalent diameter of the second particle 23 is preferably not less than 300 nm and not more than 700 nm, and more preferably not less than 400 nm and not more than 700 nm.

The sphere-equivalent diameter of the first particle 22 is 1/10 or less of the wavelength of the light emitted from the light emitting layer 13, and preferably 1/20 or less. The sphere-equivalent diameter of the second particle 23 is equal to the wavelength of the light emitted from the light emitting layer 13. Here, “equal to the wavelength” includes not only the case of being exactly equal but also the case of being substantially equal to the wavelength (e.g. ±50% of the wavelength).

The thickness of the first region R1 is preferably not less than 30 nm and not more than the thickness of the second region R2. This is because an excessively small thickness of the first region 22 makes it difficult to obtain the effect of reflection prevention in the first region R1, and conversely an excessively large thickness makes it necessary for the regions to be formed with a distinction and is industrially disadvantageous.

The thickness of the second region R2 is preferably 3 times or less the average of the sphere-equivalent diameters of the plurality of second particles 23. This is because an excessively large thickness thereof reduces the scattering effect of the second region R2. The thickness of the second region R2 is preferably 1.5 times or less the average of the sphere-equivalent diameters of the plurality of second particles 23. This is because the effect expected tends to be reduced as second particles 23 become more multiple layers.

In addition, when the absolute refractive index of the first region R1 is denoted by n, the average thickness of the first region R1 is denoted by d (nm), the wavelength of the light passing through the first region is denoted by λ (nm), and m is an integer of 0 or more, Mathematical Formula 1 is preferably satisfied.

(0.15+m/2)×λ≦nd≦(0.35+m/2)×λ [Mathematical Formula 1]

In the semiconductor light emitting element 110 according to the embodiment, characteristics of the transmittance T like those shown in FIG. 3B are obtained by providing the optical layer 20 including the first particle 22 and the second particle 23 like the above. That is, in the semiconductor light emitting element 110 according to the embodiment, the first region R1 including the first particle 22 provides a reflection prevention effect in the case where the incident angle θc is small (e.g. not more than the critical angle), and the second region R2 including the second particle 23 provides diffraction and scattering effects in the case where the incident angle θc is large (e.g. not less than the critical angle). Thereby, a reflection prevention effect and diffraction and scattering effects that cannot be achieved by the semiconductor light emitting element including the concave-convex 15 shown in FIGS. 2A and 2B are obtained, and an improvement in the light extraction efficiency is achieved.

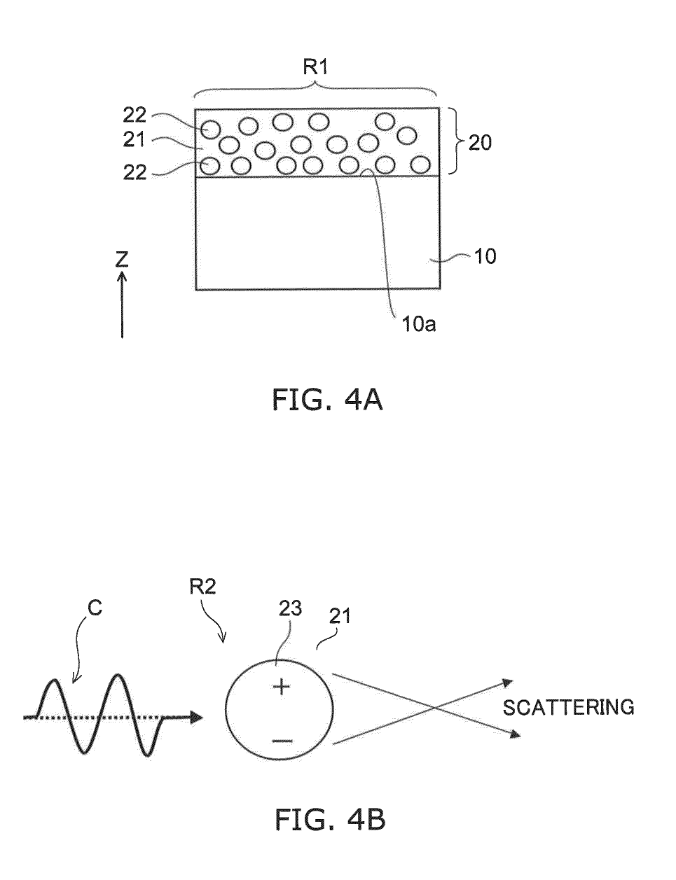

FIGS. 4A and 4B are schematic diagrams showing effects of the optical layer.

FIG. 4A is a schematic view showing the reflection prevention effect, and FIG. 4B is a schematic diagram showing the scattering effect.

First, the reflection prevention effect by the first region R1 including the first particle 22 and the dielectric body 21 is described.

As shown in FIG. 4A, the first region R1 of the optical layer 20 provided on the major surface 10a of the stacked body 10 has a reflection prevention effect. For example, when the sphere-equivalent diameter of the first particle 22 is made approximately 1/10 or less of the wavelength or preferably smaller than approximately 1/20 of the wavelength, first particles 22 are scattered at an almost fixed intensity for all the scattering angles.

When first particles 22 are uniformly scattered in the dielectric body 21, the scattered light due to first particles 22 per unit volume is equal to the sum of the light due to scattering corresponding to the number of first particles 22 scattered in a unit volume as illustrated in Mathematical Formula 2.

I(θ, φ)=Σiⱼ(θ, φ)≈×n [Mathematical Formula 2]

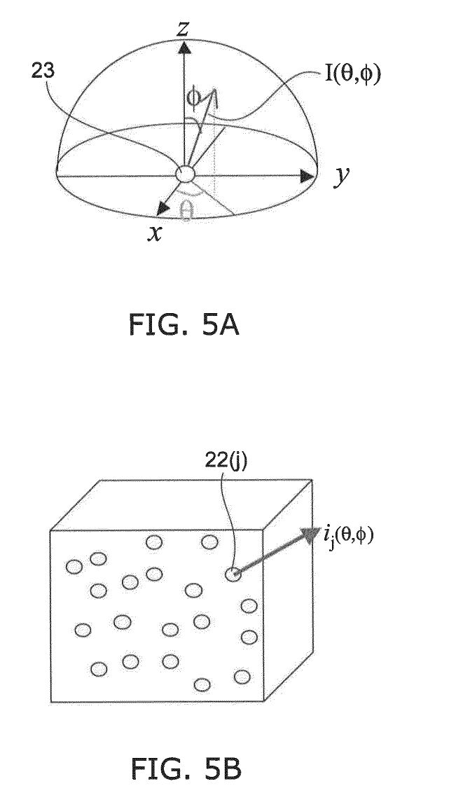

FIGS. 5A and 5B are schematic diagrams illustrating the parameters of Mathematical Formula 2.

Here, I(θ, φ) is the intensity of scattered light due to first particles 22 per unit volume in the direction of the angle (θ, φ) shown in FIG. 5A, i_{j(θ, φ)} is the intensity of scattered light due to the first particle 22(j) of the j-th in the direction of the angle (θ, φ) shown in FIG. 5B, i is the intensity normalized with respect to the solid angle of scattered light due to the single first particle 22(j), and n is the number of first particles 22 per unit volume.

As can be seen from Mathematical Formula 2, the dielectric body 21 containing very small first particles 22 with a size of approximately 1/10 of the wavelength of the light transmitted does not act as a scatterer having an angle dependence.

Next, the optical behavior of the dielectric body 21 containing very small first particles 22 with a size of approximately 1/10 of the wavelength of the light transmitted is described. Maxwell-Garnett has revealed that the effective dielectric constant of a complex (the first region R1) including the first particle 22 and the dielectric body 21 changes in accordance with the relationship of Mathematical Formula 3.

$${ɛ}_{eff} = {ɛ}_{m} ( 1 + \frac{3 δ ( {ɛ}_{p} - {ɛ}_{m} )}{( 2 {ɛ}_{p} + {ɛ}_{m} ) - δ ( {ɛ}_{p} - {ɛ}_{m} )} ) \qquad [ Mathematical Formula 3 ]$$

Further, the refractive index is expressed by Mathematical Formula 4 from the dielectric constant.

n_{eff}=\sqrt{ε_{eff}} [Mathematical Formula 4]

where ε_{eff} is the effective dielectric constant of the complex (the first region R1) including the first particle 22 and the dielectric body 21, εₚ is the dielectric constant of the first particle 22, εₘ is the dielectric constant of the dielectric body 21, d is the volume fraction of first particles 22 in the complex (the first region R1) including the first particle 22 and the dielectric body 21, and n_{eff} is the effective refractive index of the complex (the first region R1) including the first particle 22 and the dielectric body 21.

Thus, the first region R1 acts as a medium having a refractive index (an average refractive index) obtained by averaging the refractive index of the dielectric body 21 and the refractive index of the first particle 22 on a volume ratio basis.

By setting the average refractive index of the first region R1 to a value between the refractive index of the stacked body 10 and the refractive index of the outside (e.g. the refractive index of air, 1), the reflection at the major surface 10a of the light traveling from the interior of the stacked body 10 toward the outside is reduced. Consequently, the transmittance T of light is improved.

In the case where, as an example, GaP (refractive index: 3.2) is use for the stacked body 10, SiO₂ (refractive index: 1.45) is used for the dielectric body 21, TiO₂ (refractive index: 2.5) is used for the first particle 22, and the volume ratio between the first particle 22 and the dielectric body 21 is set to 1:1, the average refractive index is approximately 2.0.

The transmittance T of light from the stacked body 10 to the outside in the case of including the optical layer 20 thus configured is 16×2.0²×3.2/(1+2.0)²×(2.0+3.2)²=84%.

On the other hand, the transmittance T of light from the stacked body 10 to the outside in the case of not including the optical layer 20 is 4×3.2/(1+3.2)²=73%.

Here, when the thickness (the thickness with the major surface 10a as a reference) t1 (see FIG. 3A) of the first region R1 is set to the condition expressed by Mathematical Formula 1, the light reflected from the first region R1 to the interior of the stacked body 10 is canceled. Consequently, the quantity of light transmitted from the first region R1 to the external medium is increased. Thereby, at the major surface 10a that is a light extraction surface of the semiconductor light emitting element 110, Fresnel reflection within the critical angle is reduced, and the transmittance T of light emitted frontward is improved.

Due to the change in the effective refractive index of the first region R1, also the scattering intensity of light due to the second particle 23 changes.

Thus, in the semiconductor light emitting element 110 of the embodiment, the first region R1 of the optical layer 20 provides a reflection prevention effect to improve the transmittance T of light.

The average refractive index of the first region R1 is adjusted by the volume ratio between the dielectric body 21 and the first particle 22. Thus, the average refractive index is adjusted by the volume ratio of first particles 22 without changing the material of the dielectric body 21 and the material of the first particle 22.

In the embodiment, the average refractive index of the first region R1 is finely set by the volume ratio of first particles 22 based on the refractive index of the material of the stacked body 10, the refractive index of the material of the second particle 23 included in the second region R2, etc.

Thereby, even when the refractive index cannot be adjusted by alterations of the materials of the dielectric body 21 and the first particle 22, an optimum refractive index is selected by the volume ratio of first particles 22, and an improvement in the light extraction efficiency by a reflection prevention effect is achieved.

Next, the light scattering and diffraction effects by the second region R2 including the second particle 23 and the dielectric body 21 are described.

As shown in FIG. 4B, the second particle 23 included in the second region R2 of the optical layer 20 provided on the major surface 10a of the stacked body 10 exhibits a light scattering effect. For example, when light C is incident on the second particle 23 having a sphere-equivalent diameter approximately equal to the wavelength, polarization occurs in the second particle 23. The light C is scattered by the polarization.

When light having a wavelength approximately equal to the sphere-equivalent diameter is caused to be incident on a single second particle 23, the light is scattered with an angle dependence. The light scattered changes with the wavelength of the light, the size of the second particle 23, and the absolute value of the difference between the refractive index of the second particle 23 and the refractive index of the dielectric body 21. In other words, the second particle 23 with a sphere-equivalent diameter of approximately one to several times the wavelength of the light transmitted has a refractive index different from the effective refractive index of the complex (the first region R1) including the first particle 22 and the dielectric body 21 described above; thereby, a scattering phenomenon occurs.

At this time, at the single second particle 23, the intensity of forward scattering of the scattered light is smaller than 1/100 of the intensity of backward scattering. Thus, light loss at not less than the critical angle at the major surface 10a that is a light extraction surface is reduced.

In view of the fact that the refractive index of the dielectric body 21 that is a scattering medium used is larger than the refractive index of air, forward scattering is sufficiently great when the sphere-equivalent diameter of the second particle 23 is larger than 300 nm. However, if the sphere-equivalent diameter of the second particle 23 is as large as several times the wavelength, a scattering having an angle dependence in accordance with the shape of the second particle 23 occurs. The sphere-equivalent diameter of the second particle 23 is preferably approximately less than 1000 nm. This is because backward scattering is strong when the sphere-equivalent diameter of the second particle 23 is 1000 nm or more.

Here, in the case where second particles 23 are sparse and the spacing between adjacent second particles 23 and the arrangement are random, the scattering of light due to a single second particle 23 can be regarded as occurring at each of the plurality of second particles 23. In other words, when a large number of second particles 23 exist in the dielectric body 21, the scattering intensity due to the second particle 23 increases with the concentration of second particles 23.

On the other hand, when the concentration of second particles 23 exceeds a certain value and the distance between adjacent second particles 23 becomes short, scattered light rays interact with one another and a diffraction phenomenon is thus caused. When diffraction occurs, the scattering intensity is increased for angles satisfying diffraction.

An investigation by the inventors of this application has revealed that, as a condition whereby the scattering intensity is increased by diffraction, the distance (the center-of-mass distance) between adjacent second particles 23 is not less than 1.1 times and not more than 3 times the average of the sphere-equivalent diameters of the plurality of second particles 23.

That is, the lower limit of the spacing between second particles 23 is approximately the most proximity. The upper limit of the spacing between second particles 23 is preferably set not more than a spacing at which the occupation area of second particles 23 is approximately 10% (not more than 3 times the average of the sphere-equivalent diameters of the plurality of second particles 23). Exceeding this upper limit reduces the intensity of diffracted light to result in a reduced effect.

The second particles 23 included in the second region R2 are preferably three layers or less in the Z direction. When the second particles 23 are three layers or less, sufficient light by the diffraction of light is extracted to the outside. Further, to prevent the scattered light from being backward scattered, the second particles 23 are preferably one layer in the Z direction.

To make the second particles 23 three layers or less in the Z direction as mentioned above, the thickness (the thickness with the major surface 10a as a reference) t2 (see FIG. 3A) of the second region R2 is less than 3000 nm, preferably 3 times or less the average of the sphere-equivalent diameters of the plurality of second particles 23, and more preferably 1.5 times or less.

To cause scattering and diffraction, the thickness t2 of the second region R2 is preferably not less than the thickness t1 of the complex (the first region R1) composed of the first particle 22 and the dielectric body 21.

Thus, light of not less than the critical angle resulting from the refractive index of the stacked body 10 is scattered by the second particle 23 having a sphere-equivalent diameter of approximately one to several times the wavelength of the light transmitted, and light is thus extracted to the outside. Thereby, of the light C having an incident angle θc of not less than the critical angle with respect to the major surface 10a that is a light extraction surface, components that might be lost by total reflection at the major surface 10a are extracted to the outside.

The light reflection prevention effect increases as the proportion of the area of the first region R1 in the optical layer 20 increases as viewed in the Z direction, and the light scattering and diffraction effects increase as the proportion of the area of the second region R2 in the optical layer 20 increases as viewed in the Z direction. In view of the balance between both, the proportion of the area of the second region R2 is preferably approximately not less than 5% and less than 50%.

If the proportion of the area of the second region R2 is less than 5%, the light scattering effect is too small; and those of approximately 5% or more provide an increased efficiency of extracting light of not less than the critical angle. On the other hand, if the proportion is 50% or more, the region where Fresnel reflection can be reduced is small and the light transmittance T at not more than the critical angle, other than diffraction angles, is reduced. Furthermore, those of 50% or more make it difficult to make a functional separation between the light reflection prevention effect by the first region R1 and the light scattering and diffraction effects by the second region R2. Therefore, the proportion of the area of the second region R2 is preferably less than 50%.

As the dielectric material used for the first particle 22 and the second particle 23, a material is used that has a relatively large refractive index, in view of the refractive index of the stacked body 10 being approximately not less than 2 and not more than 3.5, and does not cause light absorption by the material at a desired wavelength of light. For example, the first particle 22 and the second particle 23 are made of an oxide or a nitride of at least one selected from the group consisting of titanium, zinc, tin, indium, zirconium, silicon, and tungsten or polystyrene. As the material of the dielectric body 21 in which first particles 22 and second particles 23 are scattered, silicon oxide, an epoxy resin, and a silicone resin are preferable.

In the case where, for example, the effect of reducing Fresnel reflection for visible light is obtained using such materials, the thickness t1 of the first region R1 including the first particle 22 and the dielectric body 21 is preferably approximately 30 nm or more due to the constraint of the refractive index and the wavelength.

Thus, in the semiconductor light emitting element 110 according to the embodiment, by the first region R1 and the second region R2 of the optical layer 20, a light reflection prevention effect and light scattering and diffraction effects are exhibited and the light extraction efficiency is improved.

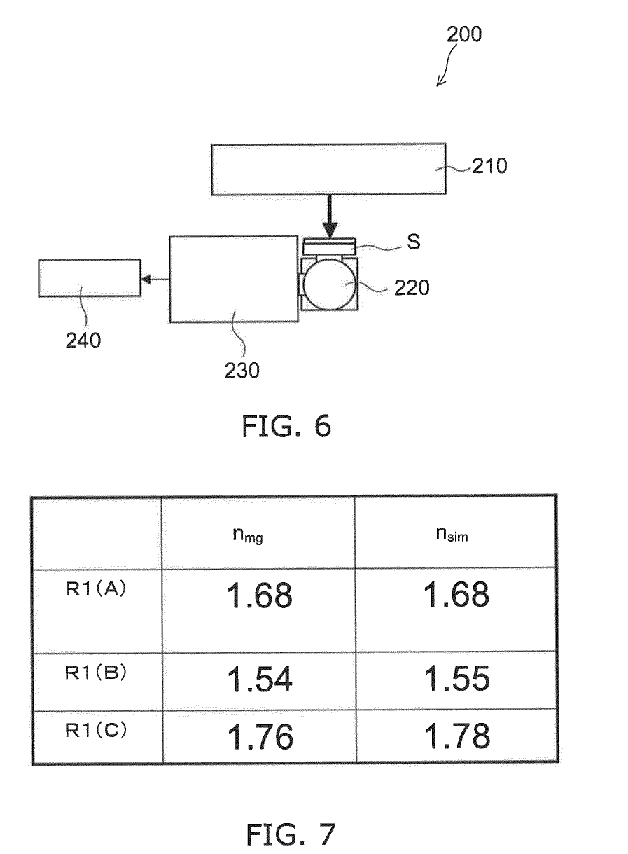

FIG. 6 is a schematic diagram illustrating the configuration of a measurement apparatus of the light extraction efficiency.

As shown in FIG. 6, a measurement apparatus 200 includes a light source 210, an integrating sphere 220, a detection unit 230, and an output unit 240. A sample S of which the light extraction efficiency is measured is placed at the integrating sphere 220. The sample S is irradiated with ultraviolet light (e.g. wavelength: 254 nm) from the light source 210. The light thereby emitted from the sample S is collected by the integrating sphere 220 and is detected by the detection unit 230. The output unit 240 outputs the detection result.

The light extraction efficiency of the sample S is measured using the measurement apparatus shown in FIG. 6.

The optical film 20 is fabricated by the following processes.

First, a TiO₂ particle paste (PST-400C; manufactured by JGC Catalysts and Chemicals Ltd.) is weighed out to obtain an SOG solution (OCD-T7 T-5500; manufactured by Tokyo Ohka Kogyo Co., Ltd.) with a TiO₂ particle paste content of 3 weight percent, and is sufficiently dispersed by ultrasonic irradiation. Then, the mixture is filtered through a PTFE (polytetrafluoroethylene) filter with a pore size of 5.0 μm to obtain a dispersion solution of TiO₂ particles.

Next, the dispersion solution is applied onto a substrate by spin coating at 2000 rpm, and baking treatment at 120° C. for 90 seconds is performed on a hot plate. Then, the SOG solution is cured by heating at 300° C. for 30 minutes under a nitrogen atmosphere; thus, the optical film 20 is completed.

The average refractive index of the first region R1 in the optical film 20 completed is approximately 1.45, the thickness t1 of the first region R1 is approximately 400 nm, and the refractive index of the TiO₂ is 2.5.

The light extraction efficiency is measured for each of a first sample of only a GaP substrate and a second sample in which the optical film 20 mentioned above is formed on a GaP substrate.

Assuming that the light extraction efficiency in the first sample is 1, the light extraction efficiency in the second sample is approximately 2.9. As a reference example, the light extraction efficiency in a third sample having a concave-convex 15 like that shown in FIG. 2A is approximately 2.6.

When the optical film 20 of the second sample is provided on a red LED with a charge injection electrode formed, the maximum brightness is improved to approximately 2.0 times as compared to the case where the optical film 20 is not provided.

Next, optical simulations are described. Herein, simulation results using the RCWA (rigorous coupled wave analysis) method are described as examples.

First, it is illustrated that the effective refractive index changes with a medium (corresponding to the first region R1) in which first particles 22 having a sphere-equivalent diameter of 1/10 or less of the wavelength of the light transmitted are scattered in the dielectric body 21.

FIG. 7 is a diagram showing the relationship between the first region and the refractive index.

FIG. 7 shows the refractive index n_{mg} obtained from Maxwell-Garnett and the refractive index nₛᵢₘ obtained from a simulation calculation in regard to three kinds of first regions R1(A), R1(B), and R1(C).

The first region R1(A) is a region in which the thickness t1 is 520 nm, the sphere-equivalent diameter of the first particle 22 is 50 nm, the refractive index of the first particle 22 is 1.8, the refractive index of the dielectric body 21 is 1.4, and the density of first particles 22 is 60 vol %.

The first region R1(B) is a region in which the thickness t1 is 275 nm, the sphere-equivalent diameter of the first particle 22 is 25 nm, the refractive index of the first particle 22 is 1.6, the refractive index of the dielectric body 21 is 1.5, and the density of first particles 22 is 40 vol %.

The first region R1(C) is a region in which the thickness t1 is 140 nm, the sphere-equivalent diameter of the first particle 22 is 10 nm, the refractive index of the first particle 22 is 2.5, the refractive index of the dielectric body 21 is 1.6, and the density of first particles 22 is 20 vol %.

In the first region R1(A), the refractive index n_{mg} obtained from Maxwell-Garnett is 1.68, and the refractive index nₛᵢₘ obtained from the simulation calculation is 1.68.

In the first region R1(B), the refractive index n_{mg} obtained from Maxwell-Garnett is 1.54, and the refractive index nₛᵢₘ obtained from the simulation calculation is 1.55.

In the first region R1(C), the refractive index n_{mg} obtained from Maxwell-Garnett is 1.76, and the refractive index nₛᵢₘ obtained from the simulation calculation is 1.78.

As illustrated above, it is found that the refractive index nₛᵢₘ obtained from the simulation calculation almost agrees with the refractive index n_{mg} obtained from Maxwell-Garnett.

In the first region R1, adjustment is made using the size and refractive index of the first particle 22 and the refractive index and film thickness of the dielectric body 21 to obtain an arbitrary refractive index.

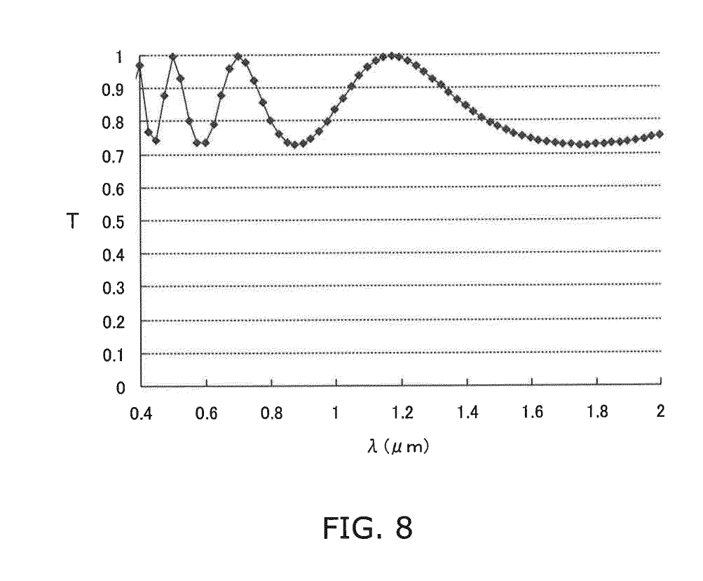

FIG. 8 is a diagram illustrating simulation results showing the relationship between the wavelength and the light transmittance.

FIG. 8 shows simulation calculation results (spectrum distribution) of the relationship between the wavelength λ (μm) and the light transmittance T for an optical film similar to the first region R1(A) shown in FIG. 7.

As shown in FIG. 8, the optical film similar to the first region R1(A) exhibits the characteristic that the light transmittance T becomes high at specific wavelengths A. That is, it is found that a high reflection prevention effect is obtained at the wavelengths A at which the light transmittance T becomes high.

The spectrum distribution shown in FIG. 8 changes with the average refractive index of the first region R1 formed on a substrate in which first particles 22 having a sphere-equivalent diameter of 1/10 or less of the wavelength of the light transmitted are scattered. Therefore, the average refractive index of the first region R1 can be calculated from the spectrum distribution.

Next, simulation results of scattering in the second region R2 are described.

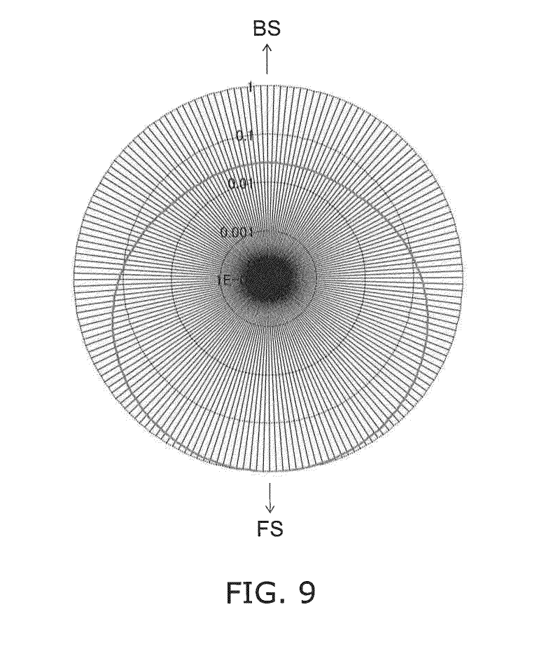

FIG. 9 to FIG. 11 are diagrams illustrating simulation results of the direction of scattering due to the second particle.

In the drawings, FS indicates the direction of forward scattering, and BS indicates the direction of backward scattering. The scattering is relative values on the assumption that the maximum value is 1.

FIG. 9 shows scattering in the case where the sphere-equivalent diameter of the second particle 23 is 200 nm, the refractive index of the second particle 23 is 1.5, the refractive index of the dielectric body 21 is 1.0, and the wavelength is 400 nm.

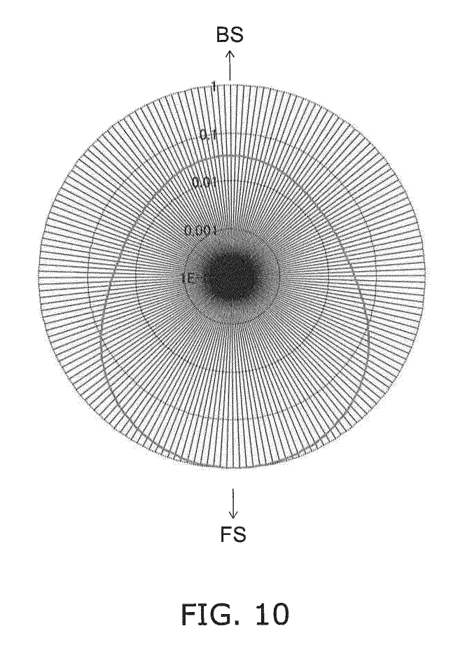

FIG. 10 shows scattering in the case where the sphere-equivalent diameter of the second particle 23 is 300 nm and the other conditions are the same as FIG. 9.

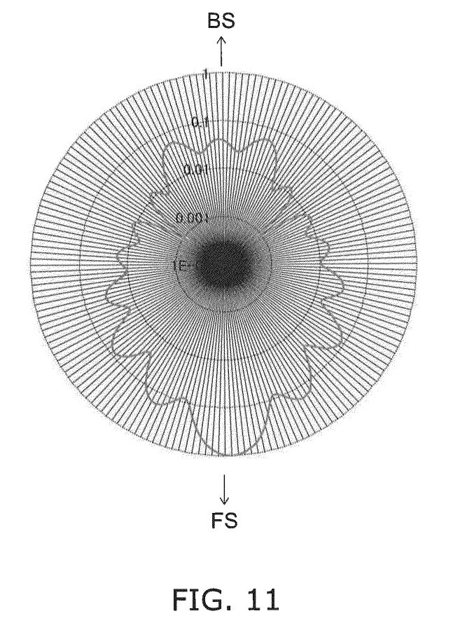

FIG. 11 shows scattering in the case where the sphere-equivalent diameter of the second particle 23 is 1000 nm and the other conditions are the same as FIG. 9.

From the simulation results mentioned above, forward scattering is stronger in the case shown in FIG. 10 where the sphere-equivalent diameter of the second particle 23 is 300 nm than in the case shown in FIG. 9 where the sphere-equivalent diameter of the second particle 23 is 200 nm. On the other hand, when the sphere-equivalent diameter of the second particle 23 is 1000 nm as shown in FIG. 11, the direction dependence of scattering is strong as compared to the case shown in FIG. 10 where the sphere-equivalent diameter of the second particle 23 is 300 nm.

Thus, the sphere-equivalent diameter of the second particle 23 is preferably more than 300 nm and less than 1000 nm.

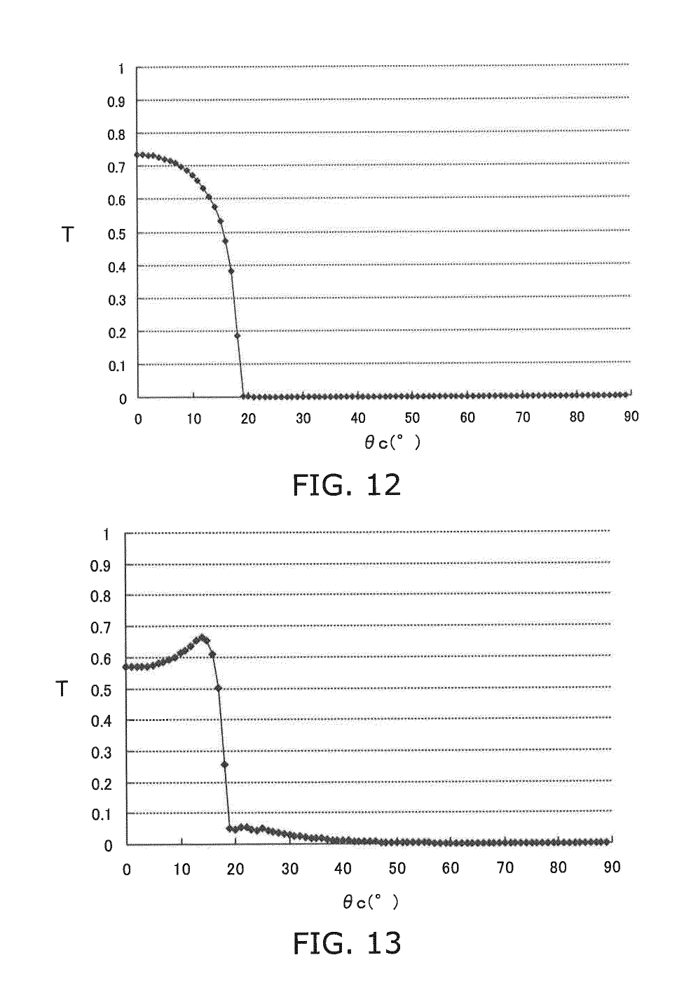

FIG. 12 to FIG. 14 are diagrams showing simulation calculation results of the light transmittance versus the incident angle θc.

In this simulation calculation, the center-of-mass distance between second particles 23, the film thickness of the dielectric body 21, and the area ratio (the proportion to the area of the major surface 10a) of second particles 23 are changed in the case where the sphere-equivalent diameter of the second particle 23 is 400 nm, the refractive index of the second particle 23 is 2.5, and the refractive index of the dielectric body 21 is 1.4.

FIG. 12 shows simulation results in the case where the center-of-mass distance between second particles 23 is 1600 nm, the film thickness of the dielectric body 21 is 30 nm, and the area ratio of second particles 23 is 5%.

FIG. 13 shows simulation results in the case where the center-of-mass distance between second particles 23 is 650 nm, the film thickness of the dielectric body 21 is 400 nm, and the area ratio of second particles 23 is 40%.

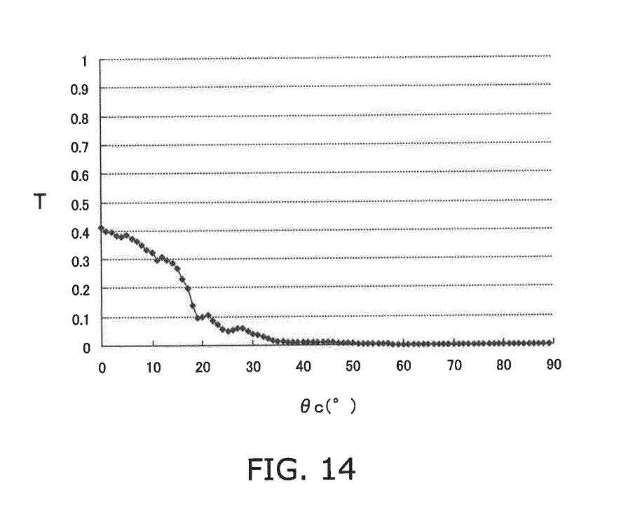

FIG. 14 shows simulation results in the case where the center-of-mass distance between second particles 23 is 500 nm, the film thickness of the dielectric body 21 is 30 nm, and the area ratio of second particles 23 is 80%.

As shown in FIG. 12, the simulation results mentioned above show that light of not less than the critical angle is totally reflected in the case where the center-of-mass distance between second particles 23 is as wide as 1600 nm and the area ratio is as low as 5%. As shown in FIG. 13, when the center-of-mass distance between second particles 23 is 650 nm and the area ratio is 40%, the light transmittance T of not less than the critical angle is increased without causing a large decrease in the light transmittance T of not more than the critical angle. As shown in FIG. 14, when the center-of-mass distance between second particles 23 is as narrow as 500 nm and the area ratio is as high as 80%, the light transmittance T of not more than the critical angle is greatly decreased.

According to the simulation, the area ratio of second particles 23 is preferably approximately not less than 5% and not more than 50%. Thereby, in the semiconductor light emitting element 110 according to the embodiment, the light transmittance T is improved in a wide range of incident angles θc, and an improvement in the light extraction efficiency is achieved.

In the semiconductor light emitting element 110 according to the embodiment, the optical layer 20 that provides high light transmissivity for a wide range of incident angles θc is provided on the major surface 10a of the stacked body 10; thereby, the brightness properties of the semiconductor light emitting element 110 are improved.

As described above, the semiconductor light emitting element 110 according to the embodiment can improve the light extraction efficiency.

Hereinabove, embodiments and modification examples thereof are described. However, the invention is not limited to these examples. For example, one skilled in the art may appropriately make additions, removals, and design modifications of components to the embodiments or the modification examples thereof described above, and may appropriately combine features of the embodiments; such modifications also are included in the scope of the invention to the extent that the spirit of the invention is included.

For example, although the embodiments and the modification examples described above use the case where the first conductivity type is the n-type and the second conductivity type is the p-type, the invention can be practiced also by setting the first conductivity type to the p-type and the second conductivity type to the n-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element comprising:
a stacked body having a major surface and including a light emitting layer; and
an optical layer provided in contact with the major surface of the stacked body and including a dielectric body, a plurality of first particles having a refractive index different from a refractive index of the dielectric body, and a plurality of second particles having a refractive index different from a refractive index of the dielectric body,
the optical layer including:
a first region including the dielectric body and the plurality of first particles and not including the plurality of second particles; and
a second region including the dielectric body and the plurality of second particles,
a sphere-equivalent diameter of the first particle being not less than 1 nanometer and not more than 100 nanometers,
a sphere-equivalent diameter of the second particle being more than 300 nanometers and less than 1000 nanometers,
an average refractive index of the first region being larger than a refractive index of the stacked body and smaller than a refractive index of the second particle.

2. The element according to claim 1, wherein a thickness of the first region is not less than 30 nanometers and not more than a thickness of the second region.

3. The element according to claim 1, wherein the sphere-equivalent diameter of the first particle is 1/10 or less of a wavelength of light emitted from the light emitting layer.

4. The element according to claim 1, wherein the sphere-equivalent diameter of the first particle is 1/20 or less of a wavelength of light emitted from the light emitting layer.

5. The element according to claim 1, wherein the sphere-equivalent diameter of the second particle is equal to a wavelength of light emitted from the light emitting layer.

6. The element according to claim 1, wherein a thickness of the second region is 3 times or less an average of the sphere-equivalent diameters of the plurality of second particles.

7. The element according to claim 1, wherein a thickness of the second region is 1.5 times or less an average of the sphere-equivalent diameters of the plurality of second particles.

8. The element according to claim 1, wherein a proportion of an area of the second region to an area of the major surface is not less than 5 percent and not more than 50 percent as viewed in a direction perpendicular to the major surface.

9. The element according to claim 1, wherein a center-of-mass distance between adjacent ones of the plurality of second particles is not less than 1.0 time and not more than 3 times an average of the sphere-equivalent diameters of the plurality of second particles.

10. The element according to claim 1, satisfying
(0.15+m/2)×λ≦nd≦(0.35+m/2)×λ
where n is an absolute refractive index of the first region, d (nanometer) is an average thickness of the first region, λ (nanometer) is a wavelength of light passing through a first region, and m is an integer of 0 or more.

11. The element according to claim 1, wherein the dielectric body is made of at least one selected from silicon oxide, an epoxy resin, and a silicone resin.

12. The element according to claim 1, wherein the first particle is made of an oxide or a nitride of at least one selected from the group consisting of titanium, zinc, tin, indium, zirconium, silicon, and tungsten or polystyrene.

13. The element according to claim 1, wherein the second particle is made of an oxide or a nitride of at least one selected from the group consisting of titanium, zinc, tin, indium, zirconium, silicon, and tungsten or a polymer.

14. The element according to claim 1, wherein the plurality of second particles included in the second region are three layers or less in a thickness direction of the second region.

15. The element according to claim 1, wherein the refractive index of the stacked body is not less than 2.5 and not more than 3.2.

16. The element according to claim 1, wherein the refractive index of the dielectric body is not less than 1.4 and not more than 1.5.

17. The element according to claim 1, wherein the stacked body includes a first semiconductor layer of a first conductivity type, and a second semiconductor layer of a second conductivity type,
the light emitting layer is provided between the first semiconductor layer and the second semiconductor layer, and
the first semiconductor layer includes a first cladding layer.

18. The element according to claim 1, wherein
the stacked body includes a first semiconductor layer of a first conductivity type, and a second semiconductor layer of a second conductivity type,
the light emitting layer is provided between the first semiconductor layer and the second semiconductor layer, and
the second semiconductor layer includes a second cladding layer.

19. The element according to claim 18, wherein the second semiconductor layer includes a current spreading layer provided on the second cladding layer.

20. The element according to claim 19, wherein the second semiconductor layer includes a contact layer provided on the current spreading layer.
